(19) United States
(12) Patent Application Publication
(10) Pub. No.: US 2026/0023143 A1
(43) Pub. Date: Jan. 22, 2026

(54) SYSTEM, METHOD, AND COMPUTER ACCESSIBLE MEDIUM FOR POPULATION RECEPTIVE FIELD DECODING

(71) Applicant: New York University, New York, NY (US)

(72) Inventors: SEBASTIAN WAZ, New York, NY (US); YALIN WANG, Tempe, AZ (US); ZHONG-LIN LU, New York, NY (US)

(21) Appl. No.: 19/264,350

(22) Filed: Jul. 9, 2025

Related U.S. Application Data
(60) Provisional application No. 63/673,223, filed on Jul. 19, 2024.

(51) Int. Cl. G01R 33/48; G06T 11/00

(52) U.S. Cl. CPC G01R 33/4806; G06T 11/008; G06T 2211/424

(57) ABSTRACT

Exemplary systems, methods and computer-accessible medium according to the exemplary embodiments of the present disclosure are provided for rapidly decoding a population receptive field (PRF) model by generating or providing a plurality of prototypes within a visual field, wherein each of the prototypes comprises an output prediction for the PRF model based on a predetermined stimulus and at least one unique parameter combination, identifying, from the plurality of prototypes, a closest matching prototype for a blood-oxygenation-level-dependent (BOLD) signal, searching a group of parameter combinations associated with the closest matching prototype to determine a refined parameter combination that more closely matches the BOLD signal than the closest matching prototype, reiterating the search among at least one neighbor of the refined parameter combination until no neighboring combination improves the match, and estimating an uncertainty measure associated with the refined parameter combination using a variational inference procedure or another Bayesian inference method.

### CROSS-REFERENCE TO RELATED APPLICATION(S)

This application relates to and claims priority from U.S. Patent Application No. 63/673,223, filed on Jul. 19, 2024, the entire disclosure of which is incorporated herein by reference.

### STATEMENT REGARDING FEDERALLY FUNDED RESEARCH

This invention was made with government support under R01 EY032125 awarded by the National Institutes of Health. The government has certain rights in the invention.

### FIELD OF THE DISCLOSURE

The present disclosure relates generally to systems, methods and computer-accessible medium for accelerating and/or improving population receptive field decoding.

### BACKGROUND INFORMATION

Retinotopic maps are representations of the visual field on the surface of the brain and have been a subject of scientific inquiry for at least a century (see, e.g., Ribeiro et al., 2024). These maps were established in large part initially by studies of brain lesions suffered by people injured in war (see, e.g., Glickstein and Whitteridge, 1987; Inouye, 1909; and Holmes and Lister, 1916), and subsequently by surgical investigations in homologues. Although physiological measurements of retinotopic maps were made as early as the 1980s using positron emission topography (see, e.g., Fox et al., 1986; and Fox et al., 1987), it was not until the 1990s that the current conventions for studying retinotopic maps began to emerge (see, e.g., De Yoe et al., 1996;Dumoulin et al., 2003; Engel et al., 1994; Engel et al., 1997; Sereno et al., 1995), namely, the use of functional magnetic resonance imaging (fMRI) to detect blood-oxygenation-level-dependent (BOLD) signals which were phase-locked to visual stimulation. Based on these developments, Dumoulin and Wandell (2008) formulated the population receptive field (PRF) model which has become a standard model in retinotopic mapping.

The PRF model has had a significant impact within visual neuroscience, with the original article of Dumoulin and Wandell (2008) having 744 citations according to Scopus as of July 2022, with a Field-Weighted Citation Impact of 4.87, indicating a citation rate nearly 5 times that of comparable articles on average. The PRF model is currently used as a standard basis for identifying the layout and boundaries of the visual areas (see, e.g., Dougherty et al., 2003, Benson et al., 2022, and Himmelberg et al., 2023) which, subsequently, enables neuroscientists to study the functional specialization of the regions of the brain (see, e.g., Silver and Kastner, 2009). The PRF model has seen a number of subsequent iterations (see, e.g., Kay et al., 2013; Haak et al., 2013; and Zeidman et al., 2018).

The PRF model has also shown promise as an endpoint in clinical applications. In Alzheimer's disease (AD), visual deficits are commonly reported as an early symptom, and these deficits have been associated with reduced surface area of the retinotopic maps in the brains of patients with AD relative to controls (see, e.g., Brewer and Barton, 2014; and Brewer et al., 2016). Glaucoma, a disease which leads to damage of the optic nerve, can be assessed with fMRI (see, e.g., Duncan et al., 2007; and Boucard et al., 2009), and thus PRF modeling can be useful in tracking its progression (thus making it useful as an endpoint for medications in treating glaucoma). Although the PRF model is not currently used in neurosurgery, the publication by Hense et al. (2021) has shown that retinotopic organization can be reliably assessed in pre-operative patients with tumors and/or lesions of the occipital lobe. Similar technologies have been used in the pre-surgical planning and post-surgical assessment of patients receiving an implant for deep brain stimulation (see, e.g., Lauro et al., 2018). The success of these interventions suggests that the PRF model might be useful in future neurosurgery for patients dealing with visual impairments like those described above (see, e.g., Bridge, 2011). For those with stroke-induced cortical lesions, retinotopic maps may also be reliably estimated (see, e.g., Elshout et al., 2021), and their corresponding visual deficits may be recovered using noninvasive interventions such as visual restitution training (VRT); the improvement observed under VRT is associated with increased PRF size within the cortical representation of the blind field (see, e.g., Barbot et al., 2021). In patients suffering macular degeneration (MD), a disease marked by central retina damage (see, e.g., Bridge, 2011), peripheral stimulation has been found to activate the foveal confluence (see, e.g., Baker et al., 2005), suggesting passive adaptation in the visual system of those with MD that resembles the adaptation achieved by VRT.

However, the possibility of leveraging the PRF model to its greatest extent in any of these domains can depend, at least in part, on the usability of the model in practice. Despite its success in modeling retinotopic maps and broad adoption in the research community, computing the PRF can be very time consuming. For a single brain with 91,282 vertices, it can take a long time (e.g., up to 194 hours) to generate a complete PRF solution. The time intensive nature of computing estimates for the PRF model prohibits many researchers who do not have access to high-performance computing from making practical use of the PRF model. In addition, because it can be difficult to visualize retinotopic data before it is analyzed with the PRF model, PRF estimation may need to be repeated multiple times as changes are made in the preprocessing steps. Consequently, the time demands imposed by PRF estimation pose an obstacle to developing and debugging any system which incorporates the PRF model into its processing pipeline.

Accordingly, it can be beneficial to provide systems, methods, and computer accessible medium which can overcome at least some of the deficiencies described herein above by improving not only the speed of decoding the PRF model, but also the information available from PRF model.

### SUMMARY OF THE EXEMPLARY EMBODIMENTS

The following is intended to be a brief summary of the exemplary embodiments of the present disclosure and is not intended to limit the scope of the exemplary embodiments.

In some exemplary embodiments of the present disclosure, exemplary systems, methods, and computer accessible medium can be provided for decoding a population receptive field (PRF) model. The exemplary systems, methods, and computer accessible medium can, e.g., generate or providing a plurality of prototypes within a visual field, wherein each of the prototypes comprises an output prediction for the PRF model based on a predetermined stimulus and at least one unique parameter combination, identify, from the plurality of prototypes, a closest matching prototype for a blood-oxygenation-level-dependent (BOLD) signal, search a group of parameter combinations associated with the closest matching prototype to determine a refined parameter combination that more closely matches the BOLD signal than the closest matching prototype, reiterate the search among at least one neighbor of the refined parameter combination until no neighboring combination improves the match, and estimate an uncertainty measure associated with the refined parameter combination using a variational inference procedure or another Bayesian inference method.

Furthermore, exemplary systems, methods, and computer accessible medium can be configured and/or provided to search a second group of unique parameter combinations related to the determined unique parameter combination, and determine a further unique parameter combination by comparing the unique parameter combination determined from the group of related unique parameter combinations with a second group of unique parameter combinations related to the determined unique parameter combination. In some exemplary embodiments, the group of related unique parameter combinations can vary one or more parameters related to a receptive field location. According to other exemplary embodiments, the second group of unique parameter combinations vary one or more parameters related to at least one of a field size and a compressive non-linearity for an identified field location. In some exemplary embodiments, the decoding can be applied to a non-circular receptive field shape. The non-circular shape can be achieved by elongating the circular receptive field on the visual field along with a given orientation. In some exemplary embodiments, the uncertainty measure can comprise a posterior variance or an entropy associated with a receptive field estimate. Also, the variational inference procedure can comprise approximating a posterior distribution using a multivariate Gaussian or log-normal distribution parameterized by mean and variance terms that are optimized with respect to an evidence-lower-bound (ELBO). The exemplary systems, methods, and computer accessible medium can further aggregate a group of parameter estimates across a plurality of voxels using inverse-variance weighting to produce a de-noised or population-level retinotopic map. Such exemplary systems, methods, and computer accessible medium can also identify at least one spatial region of a cortical surface or a visual field where BOLD data provides a level of high information content based on the uncertainty measure being below a defined threshold.

In some exemplary embodiments of the present disclosure, exemplary systems, methods, and computer accessible medium can be provided which can decode a BOLD signal by generating a set of PRF estimates while a subject is in a functional magnetic resonance imaging scanner by determining a plurality of intervoxel relationships in real-time.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1 is an exemplary visualization of a BOLD signal at a single point within the visual cortex of a given subject and the PRF model predictions fitted to it according to an exemplary embodiment of the present disclosure;

FIG. 2 is an exemplary diagram representing an exemplary order in which parameter combinations are searched within the tree-like data structure of qPRF when fitting a BOLD signal according to an exemplary embodiment of the present disclosure;

FIG. 3 is an exemplary set of graphs providing a comparison between qPRF and analyzePRF in terms of time to compute estimates for the PRF model according to an exemplary embodiment of the present disclosure;

FIG. 4 is an exemplary heat map illustrating the difference in R² achieved by the qPRF estimation procedure and the R² values reported by Benson et al. (2018) for all vertices of the HCP data set according to an exemplary embodiment of the present disclosure;

FIG. 5 is a set of the exemplary illustrations providing an exemplary series of PRF solution comparisons between qPRF and those provided by Benson et al. (2018) according to an exemplary embodiment of the present disclosure;

FIG. 6 is an exemplary heat map providing a comparison of the R² values achieved by the qPRF method followed by neighbor-based search (e.g., Procedure 3) versus the qPRF method alone (e.g., Procedure 2) according to an exemplary embodiment of the present disclosure;

FIG. 7 is a set of the exemplary visualizations wherein shading represents the number of subjects for whom the 95% credible interval (which can be derived using a novel variational inference procedure based on qPRF) exceeds the informative limit at each vertex according to an exemplary embodiment of the present disclosure;

FIG. 8 is a set of the exemplary visualizations of the average pRF estimate for each parameter using weighted averaging (Top row—which can be derived using a novel variational inference procedure based on qPRF) versus simple averaging (Bottom row) according to an exemplary embodiment of the present disclosure;

FIG. 9 is a set of the exemplary visualizations of the standard deviation of the average pRF estimate for each parameter using weighted averaging (Top row—which can be derived using a novel variational inference procedure based on qPRF) versus simple averaging (Bottom row) according to an exemplary embodiment of the present disclosure; and

FIG. 10 is a block diagram of an exemplary embodiment of a system according to the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures and the appended claims.

### DETAILED DESCRIPTION OF THE EXEMPLARY EMBODIMENTS

The following description of the exemplary embodiments provides non-limiting

representative examples referencing numerals to particularly describe features and teachings of different exemplary aspects and exemplary embodiments of the present disclosure. The exemplary embodiments described should be recognized as capable of implementation separately, or in combination, with other exemplary embodiments from the description of the exemplary embodiments. A person of ordinary skill in the art reviewing the description of the exemplary embodiments should be able to learn and understand the different described aspects of the present disclosure. The description of the exemplary embodiments should facilitate understanding of the exemplary embodiments of the present disclosure to such an extent that other implementations, not specifically covered but within the knowledge of a person of skill in the art having read the description of embodiments, would be understood to be consistent with an application of the exemplary embodiments of the present disclosure.

According to exemplary embodiments of the present disclosure, it is possible to provide “qPRF,” e.g., exemplary systems, methods, and computer accessible medium for fitting the PRF model that speeds up the underlying computations by a factor exceeding 1000. The exemplary systems, methods and computer-accessible medium can achieve this level of acceleration by making use of a specialized data structure which stores parameter combinations of the PRF model in a searchable tree structure. Each node of the tree structure can contain not only a parameter combination, but also the pre-computed predictions of the PRF model for that parameter combination. Nodes can be related in the tree on the basis of similarity, facilitating the exemplary systems, methods and computer-accessible medium to search for an optimal parameter combination quickly. The remarkable time savings achieved by exemplary systems, methods, and computer accessible medium according to the exemplary embodiments of the present disclosure can facilitate the use of the PRF in real-time diagnosis, and eliminates the need for high-performance computers, a resource which is not universally available to visual neuroscientists and which would otherwise be necessary to make PRF estimation tractable in any reasonable amount of time. This can be a critical development in any of the research directions and clinical applications summarized above.

### Exemplary Methods

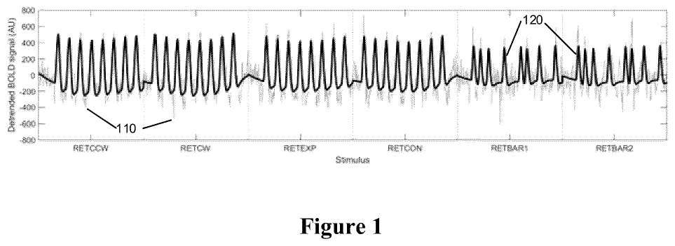

In human retinotopic mapping, the blood-oxygenation-level-dependent (BOLD) signal yielded by fMRI is the primary measurement of interest. As shown in FIG. 1, e.g., the BOLD signal 110 is a time series, which shall be denoted β(t). This exemplary time series can be associated with a single point within the cortex (usually a vertex of a mesh representing the cortical surface, but also sometimes a voxel within the cranial volume). The time series peaks when the neural activity in the given region is most active. One of the main goals of PRF modeling is to identify a location within the visual field where the pattern of stimulation matches the pattern of spikes in the BOLD signal 110. The PRF model can be formulated as follows:

$$r ( t ) = g \times {[ {\sum }_{x} {\sum }_{y} {G}_{x , y} ( {μ}_{x} , {μ}_{y} , σ ) {S}_{x y} ( t ) ]}^{n} * h ( t ) \qquad ( 1 )$$

An output quantity, which can also be referred to PRF model predictions 120, r(t), is shown in FIG. 1, and it is intended to match the BOLD signal 110 as closely as possible. The exemplary PRF model takes the stimulus (S_{x,y}(t) which is an image indexed by x and y that varies in time t), uses a circular 2-D Gaussian receptive field (G_{x,y} parameterized by μₓ,μ_{y}, and σ) to extract a sub-region of this stimulus, and integrates the activity within this sub-region using a compressive non-linearity (imposed by n), a hemodynamic response function (h(t) reflecting the general rise and decay times of neural activity upon stimulation), and a fixed gain factor (g). This yields the idealized population response, r(t). Eq. 1 explicitly denotes the five parameters of the PRF model: g,μₓ,μ_{y},σ and n. Exemplary systems, methods, and computer accessible medium according to the exemplary embodiments of the present disclosure can estimate these parameters by selecting their values to minimize the sum of squared deviations between the model and the signal, Σₜ(β(t)−r(t))². Exemplary systems, methods, and computer accessible medium according to the exemplary embodiments of the present disclosure can provide a highly time efficient way in which to perform this estimation.

FIG. 1 illustrates an overlay of the exemplary BOLD signal 110 (e.g., lighter lines) at a single point within the visual cortex of a given subject and the PRF model predictions 120 (darker lines) fitted to it. The dotted lines illustrated in FIG. 1 in the time series demarcate the beginning and end of different stimulus runs (e.g., six total, each 300 seconds in duration). In this exemplary figure, the BOLD signal 110 and PRF model predictions 120 are de-trended (i.e., each curve represents a residual after regressing on the zeroeth through third-order polynomial terms).

Techniques according to the exemplary systems, methods, and computer accessible medium of the exemplary embodiments of the present disclosure relieve a processing bottleneck that is revealed in the following pseudo-code for a typical estimation procedure:

Procedure 1 Generic PRF estimation procedure

```
Initialize θ′ ← (g,μₓ,μ_{y},σ,n)
while Fitness criterion not reached do
  if r(t) has already been evaluated for current θ′ then
        Approximate the gradient of the loss function around θ′
        Use gradient to update θ′ with new parameter estimates
      end if
    Generate vector G_{x,y} from μₓ,μ_{y}, and σ
    Multiply vector G_{x,y} with vector S_{x,y}
    Exponentiate above product by n
    Convolve exponentiated result with h(t)
    Multiply convolved result by scalar g to yield r(t)
    Compare r(t) with β(t) to check fitness criterion
end while
```

There are a number (e.g., two) important observations regarding this pseudo-code. (1) Several computations should be performed to simply evaluate r(t). Each of these computations introduces a substantial performance cost, especially those steps related to vector operations (e.g., multiplication of the 2D receptive field G_{x,y}(μₓ,μ_{y},σ) with the stimulus movie S_{x,y}(t)) and convolution (e.g., convolution of the output of the receptive field by the hemodynamic response function h(t)). These exemplary steps can be performed on every iteration of this generic estimation procedure, thus slowing the total estimation time dramatically. An important observation of the exemplary systems, methods, and computer accessible medium according to the exemplary embodiments of the present disclosure is that these steps can be approximated by a single query of a data structure stored in memory. (2) This exemplary generic estimation procedure relies on a gradient method to search the parameter space. The approximation of the gradient is a costly operation, requiring the PRF model to be evaluated at several parameter combinations around θ′ (in essence, requiring several additional iterations of the code highlighted above for evaluating r(t)). Moreover, the exemplary PRF model can be nonlinear, thus facilitating local minima to exist in the objective function.

As a result, a gradient-based parameter search may be inefficient because the search procedure may converge on a sub-optimal local minimum. In the case of analyzePRF, a standard package for PRF decoding (see, e.g., Kay et al., 2013), the gradient method used is the Levenberg-Marquardt procedure, which is known to suffer from such an inefficiency. Further, assuming the gradient is already known, this exemplary procedure uses a matrix to be formed from the gradient vector computed around θ′ and requires this matrix to be inverted. Although these operations involve relatively small matrices (5×5, with sides corresponding to the number of parameters), a single vertex can require up to 500 iterations of this exemplary procedure in analyzePRF, so the accumulation of these matrix operations can slow down PRF decoding dramatically. The second important insight of the exemplary systems, methods, and computer accessible medium according to the exemplary embodiments of the present disclosure is that search can be made much more efficient by directing the fitting procedure to pre-computed candidates that have already been organized on the basis of similarity, rather than having the fitting procedure search for candidates naively.

### Exemplary Anticipatory Modeling

The exemplary steps contained in the while-loop of Procedure 1 are conditioned only on knowing S_{x,y}(t) and having a given parameter estimate θ. Moreover, for a given retinotopy experiment, S_{x,y}(t) is typically known and fixed. Thus, in principle, exemplary systems, methods, and computer accessible medium according to the exemplary embodiments of the present disclosure can pre-compute r(t) for all parameter combinations θ in a suitably large set Θ, anticipating the parameter combinations which might be yielded by PRF modeling. This exemplary modeling can be completed according to the exemplary systems, methods, and computer accessible medium according to the exemplary embodiments of the present disclosure even before data collection has been initiated. Moreover, as is evident in FIG. 1, the BOLD signal 110 which is to be modeled is often contaminated by substantial amounts of noise. Thus, in exemplary systems, methods, and computer accessible medium according to the exemplary embodiments of the present disclosure the set of pre-evaluated parameter combinations Θ does not have to be very dense to achieve an adequate fit given typical levels of measurement noise. Further, the parameter space to be considered has a number of boundaries and empirically established trends. For example, the gain parameter g is typically assumed to be non-negative, the values of μₓ and μ_{y} should be reasonably close to the stimulus location in the visual field (if not strictly within the stimulus location), and σ increases linearly with distance of the receptive field center from the point of fixation.

In the exemplary modeling stage of the exemplary systems, methods, and computer accessible medium according to the exemplary embodiments of the present disclosure, the stimuli can be provided to the program which can evaluate the PRF model based on these stimuli for a large representative set of parameter combinations, Θ. Using the exemplary systems, methods, and computer accessible medium of the exemplary embodiments of the present disclosure, the time series 120 yielded by the PRF model evaluated at a given θ∈Θ, which is denoted r(t|θ), can be stored permanently in memory and associated with θ. By storing these exemplary results in memory, it is no longer necessary to search within Θ directly for optimal parameters; rather, it is possible to search the set of recorded r(t|θ) for a solution which minimizes the loss function Σₜ(β(t)−r(t))².

As described below, exemplary systems, methods, and computer accessible medium according to the exemplary embodiments of the present disclosure can store the values of r(t|θ) relationally, with similar values being linked together. This can mean that, once a roughly well-fitting candidate r(t|θ) is found, its relatives can be searched for a better fitting r(t|θ′). This kind of relational search can be repeated a number of times until an optimal fit is found. Since all candidate r(t|θ) values in this linked data structure have been pre-computed according to the exemplary systems, methods, and computer accessible medium according to the exemplary embodiments of the present disclosure, the work of fitting is reduced to traversing the data structure and testing only the selected candidates against β(t).

### Exemplary Searchable Tree Structure

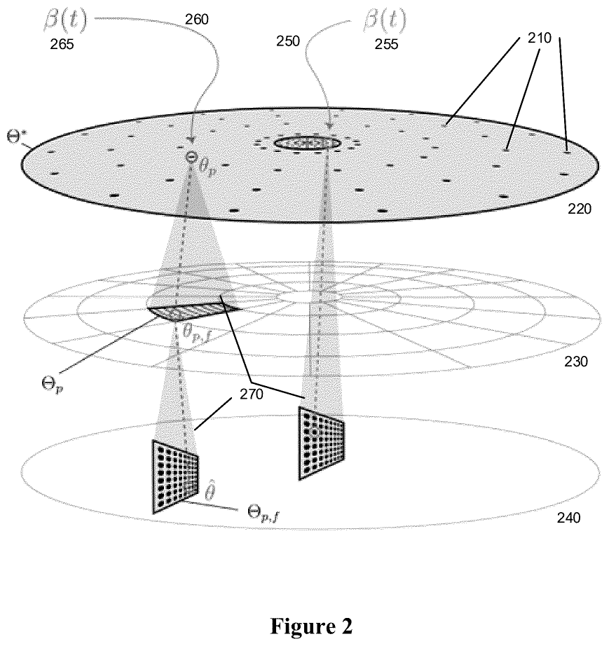

FIG. 2 shows a diagram representing an exemplary order in which parameter combinations are searched within the tree-like data structure of qPRF when fitting a BOLD signal. Each black dot 210 represents a single parameter combination. Each disk, 220, 230, and 240, represents one of the three layers of the tree structure, as well as the visual field in which the parameter combinations are embedded. The first path 250 shows an example search path for an observed BOLD signal β(t) 255 which can be best fit in the coarsest layer to a prototype within the foveal region, and the second path 260 shows an example search path for an observed BOLD signal β(t) 265 which is best fit in the coarsest layer to a prototype outside the foveal region. Shaded regions 270 encompass all of the parameter combinations which must be searched in the course of finding an optimal parameter combination. Parameter combinations can be arranged orthogonally to the disk at the lowest layer because all the parameter combinations within a partition of this layer share the same visual field location and differ only in n and σ.

Given that Θ is chosen to represent all of the reasonable parameter combinations that the given stimulus S might yield, Θ is, in general, too large to search exhaustively, so in exemplary systems, methods, and computer accessible medium according to the exemplary embodiments of the present disclosure, the recorded values of r(t|θ) for all θ∈Θ can be stored in a rapidly searchable tree structure, represented schematically in FIG. 2. To reduce the number of comparisons, exemplary systems, methods, and computer accessible medium according to the exemplary embodiments of the present disclosure can organize this data structure on the basis of similarity, selecting several prototype r(t|θ) values to be searched initially at the coarsest level. These prototypes comprise a relatively small set of examples r(t|θ) values, reflecting, as completely and concisely as possible, all of the distinct variations of r(t|θ) achievable by the PRF model. As shown in the example of FIG. 2, the top-most layer 220, which represents these prototypes, can contain parameter combinations 210 which are more sparsely distributed around the visual field than any layer below it with the exception of a small foveal region near the center of the visual field. According to the exemplary systems, methods, and computer accessible medium according to the exemplary embodiments of the present disclosure, each parameter combination 210 at the prototype layer points to a partition of the layer below it (e.g., 230), representing all the parameter combinations within the layer that are near the prototype in their location on the visual field.

Members of the foveal region can point directly to the lowest layer 240 because they already densely cover the visual field of their vicinity. In the exemplary systems, methods, and computer accessible medium according to the exemplary embodiments of the present disclosure, the clustering of the secondary layer 230 to members of the prototype layer 220 on the basis of visual field location can represent a very intuitive notion of similarity since visual field location has great influence on the shape of r(t|θ). Each parameter combination in the secondary layer 230 can subsequently point to a partition of the lowest layer 240, which represents variations of the parameters n and σ at the visual field location given by its parent. The dotted paths (255 and 265 at the second and third layers) shown in FIG. 2 can trace how parameter combinations are selected according to the exemplary systems, methods, and computer accessible medium using the exemplary embodiments of the present disclosure at each level, leading to an optimized parameter combination at the lowest level 240.

For example, θₚ can be the parameter vector of prototype p, where the set of parameter vectors θₚ for all p form a set Θ*⊂Θ. According to the exemplary systems, methods, and computer accessible medium according to the exemplary embodiments of the present disclosure, the first step of searching the data structure is to compare β(t) with r(t|θₚ) for all prototypes θₚ∈Θ* to find the best fitting member of this subset.

With the exemplary systems, methods, and computer accessible medium according to the exemplary embodiments of the present disclosure, the search can proceed similarly at the finer levels of the data structure. Each prototype p points to a subset Θₚ⊂Θ, where Θᵢ∩Θⱼ=Ø for i/=j. Once a best fitting prototype p is found at the coarsest level, Θ*, only its child subset Θₚ is searched for a better fitting member, r(t|Θ_{p,f}), where θ_{p,f}∈Θₚ. For prototypes whose elements μₓ and μ_{y} are within a small radius of the point of fixation (the foveal region), Θₚ={θₚ}, so this secondary search can be skipped. This is because, in practice, the members of the set Θ* differ primarily in μₓ and μ_{y}, and are chosen to densely sample μₓ and μ_{y} within the foveal region. Prototypes with θₚ that fall outside the region are distributed more sparsely, and this secondary search with the exemplary systems, methods, and computer accessible medium according to the exemplary embodiments of the present disclosure can be performed primarily to enhance the precision on μₓ and μ_{y} in this outer (peripheral) region.

With the exemplary systems, methods, and computer accessible medium according to the exemplary embodiments of the present disclosure, the third and final level of the data structure only represents variation in σ and n. Once a best-fitting θ_{p,f}∈Θₚ is found, its child subset Θ_{p,f}⊂Θ is searched to optimize σ and n. The optimal parameter combination found within Θ_{p,f} represents the final estimate which is returned by qPRF, which can be denoted \hat{θ}. Given μₓ, μ_{y}, σ, and n, the value of g which minimizes the sum of squared deviations can be calculated directly, so g in the exemplary systems, methods, and computer accessible medium according to the exemplary embodiments of the present disclosure is not a dimension of Θ. Further, with the exemplary systems, methods, and computer accessible medium according to the exemplary embodiments of the present disclosure, at the two coarsest levels of the tree, the σ value used among candidates can be a linear function of the distance between μₓ and μ_{y} from the fixation point (reflecting the known positive relationship between visual field eccentricity and receptive field size; see, e.g., Smith et al., 2001; Dumoulin and Wandell, 2008). Altogether, the data structure can resemble a tree, shown in FIG. 2, where the first two levels facilitate a two-phase search for an optimal receptive field location, and the third level facilitates optimization of the receptive field size and compressive non-linearity given this location.

With the exemplary systems, methods, and computer accessible medium according to the exemplary embodiments of the present disclosure, within the bottom layer of the data structure, each parameter combination \hat{θ}∈Θ_{p,f} can have associated with it a set of “neighbors'”. The neighbors of a given parameter combination \hat{θ} can comprise those other combinations within Θ which are related to \hat{θ} by an increment or decrement along any or all of its dimensions as implied by the discretization of Θ. Using these neighbor relationships, the qPRF can re-iterate its search within the bottom layer of the data structure until the loss function is found to be optimal at the current estimate relative to its neighbors.

For the test implementation of the exemplary systems, methods, and computer accessible medium according to the exemplary embodiments of the present disclosure examined below, a large number of parameter combinations can be used (e.g., a total of 1,104,960 parameter combinations). The coarsest level of the data structure, Θ*, can comprise a smaller subset of these combinations (e.g., 552 combinations), which can be called prototypes. These prototypes can be distinguished primarily by their values of μₓ and μ_{y}. Since the values of μₓ and μ_{y} are chosen to evenly cover the visual field in polar coordinates, polar parameterization ρ and ϕ are used to refer to these parameters hereafter. The foveal region, a circle of radius 0.4° at the center of the visual field, can contain a denser number of parameter combinations (e.g., 264) in Θ*, representing all combinations of 6 values of ρ (evenly spaced from 0.06 to 0.4) and 44 values of ϕ (evenly spaced from 0° to 360°, starting at 0° and ending at 351.8°). For all the foveal prototypes, n=0.1, and σ can be an increasing function of ρ (described below). As noted above, if the best fitting prototype in Θ* resides within this foveal region, the search can short circuit and skip over searching Θₚ.

With the exemplary systems, methods, and computer accessible medium according to the exemplary embodiments of the present disclosure, in contrast to the foveal prototypes, the prototypes outside the foveal region can be distributed more sparsely in ρ and ϕ because, outside the foveal region of the Θ*, all of the prototypes do point to a corresponding Θₚ with densely packed ρ and ϕ values which can be subsequently searched. The exterior of the foveal region in Θ* is itself divided into two regions, which can be referred to as the parafoveal and peripheral regions and which are separated by a circle of radius 8° in the visual field (the outer edge of the stimuli used in the HCP dataset). In the parafoveal region, there can be 160 prototypes, corresponding to all combinations of 10 values of ρ (evenly spaced within the parafoveal region spanning 0.4° to 8°) and 16 values of ϕ (evenly spaced, starting at 0°). In the peripheral region, there can be 128 prototypes representing 8 values of ρ (evenly spaced in the peripheral region spanning 8° to 16°) and 16 values of ϕ. Across all prototypes, the function used to specify σ is:

$$σ ( ρ , i ) = ( \frac{1}{120} ρ + \frac{1}{125} ) \times \frac{8}{100} \times {2}^{i} \qquad ( 2 )$$

where the units of σ and ρ are both given in degrees of visual angle. Note that for i=0 (unitless), this function roughly approximates the size-eccentricity relationship reported by Dumoulin and Wandell (2008) for V1. At the bottom layer of the data structure, the values of i used to specify the values of σ to be searched at any given value of ρ can be the integers 0 through 7. For central and para-central prototypes, the value of i can be chosen to be 4, and for peripheral prototypes, the value of i can be chosen to be 5. The values of i used among prototypes can be chosen to reflect the following known properties of receptive fields: (1) receptive field size near the fovea is markedly smaller than elsewhere in the visual field, and (2) outside the foveal region, the slope of the linear trend in receptive field size appears to increase multiplicatively with higher-order visual areas (i.e., V2 and V3, as shown by Dumoulin and Wandell, 2008). The range i∈{0 . . . 7} captures the wide variety of σ values observed across these areas.

Using the exemplary systems, methods, and computer accessible medium according to the exemplary embodiments of the present disclosure, all parafoveal and peripheral prototypes point to a child parameter space Θₚ containing 95 combinations to be subsequently searched. Thus, the total number of parameter combinations contained in the second level of FIG. 2 can equal 27,360 (288 non-foveal parent prototypes×95 combinations in each child parameter space). The 95 children of each non-foveal prototype represent combinations of 5 values of ρ and 19 values of ϕ. These values of ρ and ϕ can be centered on the ρ and ϕ values of the parent prototype and can be chosen so that the values of ρ and ϕ can form a uniform grid when considering all members of the second level in FIG. 2 (with a change in the grid resolution when going from the parafoveal to peripheral region, corresponding to a fixed number of children but a reduced number of parent prototypes).

With the exemplary systems, methods, and computer accessible medium according to the exemplary embodiments of the present disclosure, all 27,360 children of the second level of the data structure, as well as all 264 foveal prototypes, each point to a unique parameter space Θ_{p,f} which shares the values of ρ and ϕ as its parent and comprises 40 variations of n (5 levels) and σ (8 levels). Across all Θ_{p,f}, the values of n are 0.025, 0.05, 0.1, 0.2, and 0.4. The 8 values of σ represented within a given Θ_{p,f} are derived from Eq. 2 using the ρ value of the parent, and 8 evenly spaced values of i going from −4 to 4. Thus, at the finest level of the data structure, there can be (27,360+264)×40=1,104,960 parameter combinations. Although this parameter space would be massive to search exhaustively, the parent-child relationships represented by the structure with the exemplary systems, methods, and computer accessible medium according to the exemplary embodiments of the present disclosure make it so that, altogether, a vertex which is mapped to a foveal prototype will require only 552+40=592 comparisons in the course of estimation, and a vertex mapped to a parafoveal or peripheral prototype will require 552+95+40=687 comparisons.

Exemplary qPRF Basic Procedure

The following pseudocode describes the fitting procedure performed by qPRF using the exemplary systems, methods, and computer accessible medium according to the exemplary embodiments of the present disclosure.

Procedure 2 qPRF estimation procedure

```
Compare β(t) to all r(t|θₚ) for θₚ ∈ Θ* (prototype level)
Choose best fitting θₚ as current estimate \hat{θ}
if best fitting θₚ is in the parafoveal or peripheral region then
  Compare β(t) to all r(t|θ_{p,f}) for θ_{p,f} ∈ Θₚ (secondary level)
  Choose best fitting θ_{p,f} as current estimate \hat{θ}
  Compare β(t) to all r(t|θ) for θ ∈ Θ_{p,f} (final level)
  return best fitting θ as final estimate \hat{θ}
else
  Compare β(t) to all r(t|θ) for θ ∈ Θ_{p,f} (final level, child of foveal θₚ)
  return best fitting θ as final estimate \hat{θ}
end if
```

Exemplary qPRF Procedure with Neighbor-Based Search

As described above, the searchable tree can also store neighbor relationships between parameter combinations which are related by an increment or decrement along any (or all) of the parameters ρ, ϕ, σ, and n. If a closer fit is desired after completing the basic qPRF procedure (Procedure 2), the exemplary systems, methods, and computer accessible medium according to the exemplary embodiments of the present disclosure can search the neighbors of the current estimate re-iteratively until an optimal parameter combination is found with respect to all of its neighbors in the parameter space. The following pseudo-code describes this optional neighbor-based search. Note that, in this pseudo-code, the while-loop controls reiteration of the neighbor-based search while the for-loop is used to visit each neighbor of the current best estimate.

Procedure 3 Neighbor-based search

```
Complete Procedure 2 to get estimate \hat{θ}
while \hat{θ} is not optimal among its neighbors do
  for θₚ adjacent to \hat{θ} do
    Compare β(t) to r(t|θₚ)
    if r(t|θₚ) fits β(t) better than r(t|\hat{θ}) then
      \hat{θ} ← θₚ
    end if
  end for
end while
```

Exemplary Uncertainty Quantification Based on qPRF

The time savings achieved by qPRF facilitates the exemplary methods of uncertainty quantification to be performed more rapidly than previously possible. These include Bayesian methods, hierarchical models, and machine learning paradigms that require the PRF model to be evaluated iteratively during a numerical fitting procedure. As an example, a novel variational inference procedure was developed which approximates the posterior distribution using an exact fit of a Gaussian distribution to observed values of the log-likelihood. An exact fit of the Gaussian distribution to the log-likelihood was derived in the following way: (1) Once an optimal qPRF estimate for the model was achieved using Procedure 3, the log-likelihood was computed at the qPRF estimate and at each neighbor in the parameter grid. Under an exemplary model where residual noise is Gaussian distributed, the estimate from Procedure 3 which minimizes Σₜ(β(t)−r(t))² is equivalent to a maximum (log) likelihood estimator because Σₜ log p(β(t)−r(t))∝−Σₜ(β(t)−r(t))² where p is the Gaussain probability density function used to define the likelihood. (2) The log-likelihoods were interpolated linearly to match a rectangular parameter grid. (3) For each parameter, three log-likelihoods were considered: the log-likelihood of the qPRF estimate and the log-likelihoods of the two neighboring parameter values holding constant the other parameters of the qPRF estimate. A parabola was uniquely fitted to these three points. (4) The mean and variance of a Gaussian probability density was computed from the fitted parabola since the log of a Gaussian probability density function is parabolic.

### Exemplary Results

The data used in the exemplary analysis was originally sourced from the Human Connectome Project (HCP; see, e.g., Ugurbil et al, 2013; Van Essen et al., 2013) 7T Retinotopy Dataset. This dataset represents the largest publicly available collection of brain imaging data from human subjects in a retinotopy experiment. Complete details of this experiment were reported by Benson et al. (2018), who also provided PRF estimates based on this data. The PRF estimates computed by Benson et al. are available online (https://osf.io/bw9cc) and served as a reference set of estimates which can be compared against qPRF estimates of the exemplary systems, methods, and computer accessible medium according to the exemplary embodiments of the present disclosure.

The HCP dataset includes 181 subjects aged 22 to 35. For each subject, a total of 91,282 vertices were decoded with the PRF, covering both hemispheres of the cortex and subcortical regions. Of these, 29,696 (29,716) vertices represented the surface mesh of each subject's left (right) hemisphere. Thus, altogether, the dataset represents 10,753,572 unique vertices, each of which presents a single opportunity to perform PRF estimation. The cumulative BOLD signal at each vertex was a vector of 1,800 time points, comprising six runs of 300 time points (frames), with a repetition time (TR) of 1 second per frame.

The total time required to the generate qPRF estimates with the exemplary systems,

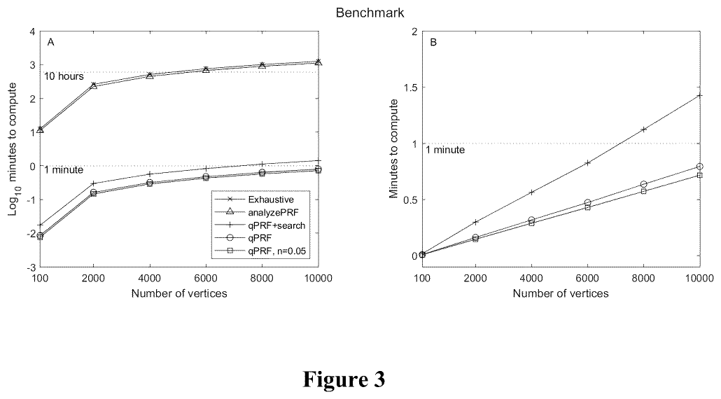

methods, and computer accessible medium according to the exemplary embodiments of the present disclosure using the basic procedure (Procedure 2) for this entire data set was 14.2 hours on e.g., a 3.50 GHz Intel Xeon E5-1650 v3 CPU. When compared to another widely available PRF decoder, analyzePRF (see, e.g., Kay et al., 2013), estimation via the qPRF of the exemplary systems, methods, and computer accessible medium according to the exemplary embodiments of the present disclosure can reduce the computation time by a factor of e.g., 1402. The comparison used to derive this factor is shown in FIG. 3. Panel A and B visualize the same information, but the y-axis of Panel A is on a logarithmic scale to allow all the strategies described herein to be compared simultaneously while the y-axis of Panel B is on a linear scale and has been zoomed in to highlight the timing differences between the qPRF strategies. The legend items “qPRF” and “qPRF+search” refer to Procedure 2 and Procedure 3 respectively, as disclosed herein.

For this comparison, the estimation was not run on the entire dataset via analyzePRF as this would be too time intensive. Instead, analyzePRF and qPRF of the exemplary systems, methods, and computer accessible medium according to the exemplary embodiments of the present disclosure were run on 10,000 vertices from the left hemisphere of HCP Subject 100610. Whereas analyzePRF can require e.g., 18.55 hours to complete this analysis, qPRF may only require e.g., 42.93 seconds. According to this benchmark, qPRF can take e.g., 4 milliseconds on average to fit a single BOLD signal, whereas analyzePRF can take e.g., 6.68 seconds.

There are three important distinctions to make as part of this comparison. (1) Both analyzePRF and qPRF use the same objective function (sum of squared deviations), but whereas the qPRF of the exemplary systems, methods, and computer accessible medium according to the exemplary embodiments of the present disclosure uses a novel procedure as specified above, analyzePRF makes use of the Levenberg-Marquardt procedure, available in Matlab as the function lsqcurvefit.m. For each vertex, analyzePRF performed up to 500 iterations of Levenberg-Marquardt procedure, returning sooner if the change in the objective function or parameter estimate was smaller than 1×10⁻⁶. (2) The exemplary analysis made use of parallel computation to speed up analyzePRF, a feature which is provided with the analyzePRF package; by contrast, the qPRF computations of the exemplary systems, methods, and computer accessible medium according to the exemplary embodiments of the present disclosure were performed serially due to the memory limitations of the benchmarking machine.

For example, even greater reductions in computation time may be achieved in exemplary systems, methods, and computer accessible medium according to the exemplary embodiments of the present disclosure by distributing the workload to multiple qPRF workers. (3) Below, the results from Benson et al. (2018) were used to compare the quality of qPRF estimates with the exemplary systems, methods, and computer accessible medium according to the exemplary embodiments of the present disclosure to a standard set of PRF estimates. Benson et al. made use of a different version of analyzePRF than the one used in the exemplary analysis. In particular, Benson et al. used a fixed value of n=0.05 whereas the exemplary analysis estimated all 5 parameters of the PRF model in Eq. 1. This likely sped up the computation time for Benson et al. since the version of analyzePRF tested here performs a two-stage estimation procedure wherein all parameters except n are first optimized under a fixed n, then all parameters including n are optimized simultaneously. Benson et al. needed only to perform the first stage of this optimization procedure to form their estimates.

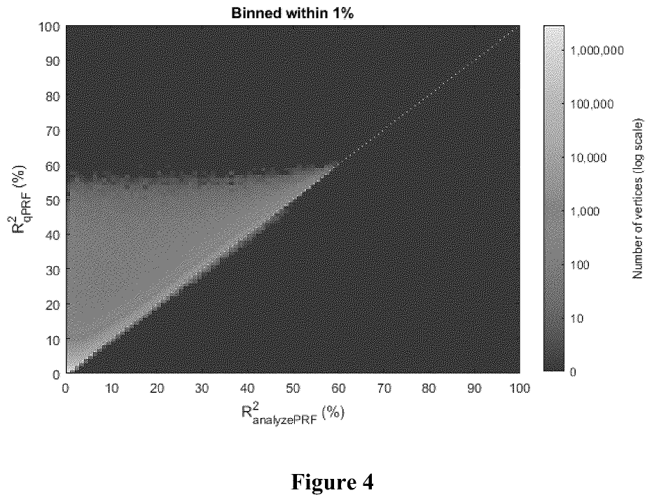

The qPRF estimates of the exemplary systems, methods, and computer accessible medium according to the exemplary embodiments of the present disclosure yielded R² measures that were markedly similar to those reported by Benson et al. (2018). FIG. 4 shows a heat map comparing R² values reported by Benson et al. (R_{Benson}²) and those achieved by the qPRF model (R_{qPRF}²) of the exemplary systems, methods, and computer accessible medium according to the exemplary embodiments of the present disclosure across all vertices of both hemispheres of all subjects in the HCP dataset. Counts are binned within 1% and are shown on a logarithmic scale. The dotted line indicates equivalence of the two solutions in terms of R². Importantly, the peak of the heat map is a ridge that closely follows the positive diagonal of the heat map, indicating equivalence between the two solutions in terms of goodness-of-fit. The distribution of vertices around this line is skewed positively, indicating that some of the qPRF estimates were better fitting than their corresponding estimates from Benson et al. (2018). Although the exemplary analysis did not re-produce their PRF estimates, Benson et al. noted that their provided estimates were based on a modified version of analyzePRF. Most notably, Benson et al. restricted n=0.05. Instead, exemplary systems, methods, and computer accessible medium according to the exemplary embodiments of the present disclosure estimated the exponent parameter, n. Discrepancies between solutions according to the exemplary systems, methods, and computer accessible medium according to the exemplary embodiments of the present disclosure and Benson could be attributed to this difference.

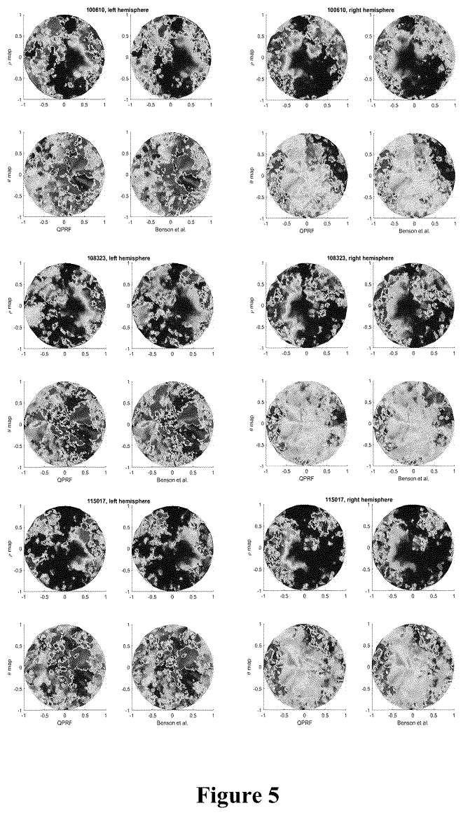

Nonetheless, when the PRF estimates from Benson and from the qPRF of the exemplary systems, methods, and computer accessible medium according to the exemplary embodiments of the present disclosure are plotted side-by-side on the cortical mesh, such as in FIG. 5, the results look strikingly similar. FIG. 5 contains six panels; each row of panels represents one subject, and each column of panels represents one hemisphere. Within each panel, the ρ estimates and θ estimates yielded by qPRF and provided by Benson et al. are projected conformally onto a parametric disk (Ta et al., 2022). Such plots are typically used as diagnostic images upon which experts may subjectively identify the boundaries of the visual areas (see, e.g., Dougherty et al., 2003, Benson et al., 2022, Himmelberg et al., 2023), so FIG. 5 can be taken to suggest that qPRF and analyzePRF offer comparable results to the end user, except that the qPRF of the exemplary systems, methods, and computer accessible medium according to the exemplary embodiments of the present disclosure is much more time efficient.

The time used to generate the data structure underlying the qPRF computation according to the exemplary systems, methods, and computer accessible medium according to the exemplary embodiments of the present disclosure was 7.95 hours. Importantly, this is much shorter than the projected total computation time for the complete HCP dataset for analyzePRF; further, this generation of the qPRF data structure according to the exemplary systems, methods, and computer accessible medium according to the exemplary embodiments of the present disclosure only needed to occur once and may be reused for any future data generated under the same stimulus specifications. The total memory required to store the data structure can be around e.g., 8.6 GB.

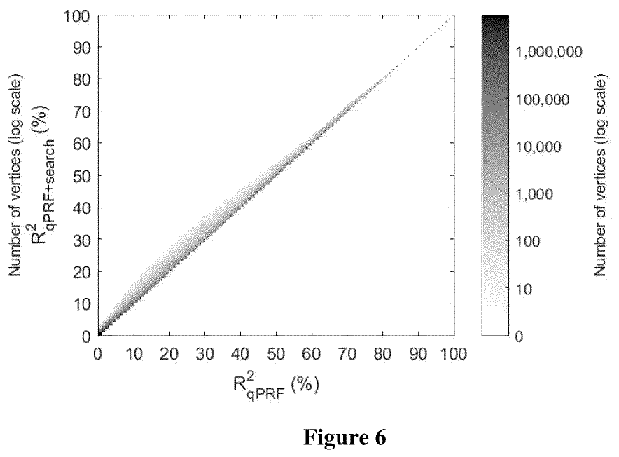

The total time required to fit the HCP dataset using neighbor-based search (Procedure 3) can be around e.g., 25.6 hours. Considering the time cost of running Procedure 3 on the benchmark of 10,000 vertices, Procedure 3 can retain high time efficiency, and reduce computation time by a factor of e.g., 781 compared to analyzePRF on the benchmark. In the heat map of FIG. 6, it is shown that the neighbor-based search can provide a marked improvement over the simpler exemplary Procedure 2 (qPRF). The improvement at some vertices can be as high as e.g., 15.1%.

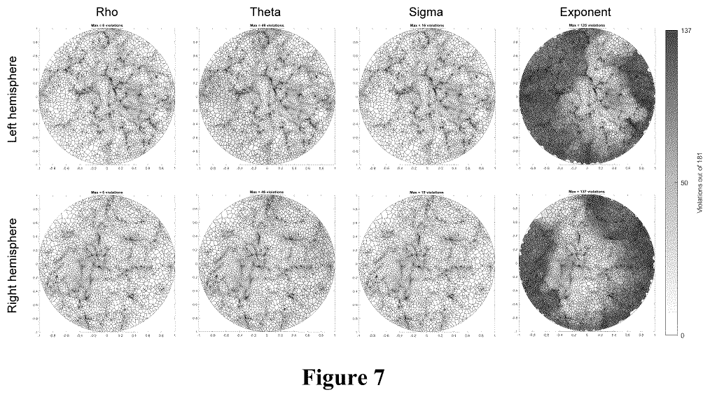

Uncertainty quantification can reveal vertices where BOLD response data can provide useable retinotopic map information based on a novel variational inference procedure. The exemplary systems, methods, and computer accessible medium according to the exemplary embodiments of the present disclosure can use an exemplary novel variational inference procedure based on qPRF, to count the number of subjects (out of 181) for whom the 95% credible interval size of each parameter violated one of the following conditions: the interval can be less than 16 degrees of visual angle for estimates of ρ, the interval can be less than 360 degrees for estimates of ϕ, the interval can be less than 4 degrees of visual angle for σ, and the interval can be less than 0.4 for estimates of n. Estimates with 95% credible intervals that violate these limits can be considered uninformative because their size exceeds the full range of parameters for the associated retinotopy test. The counts of violations are visualized in FIG. 7. Lighter regions indicate regions of the visual cortex where the majority of subjects contribute usable information about the given parameter.

To illustrate the potential value of variance quantification, the exemplary systems, methods, and computer accessible medium according to the exemplary embodiments of the present disclosure can consider how variance might be used to estimate a population-level retinotopic map. The most straightforward method to estimate the population-level retinotopic map can be simple averaging. In many scenarios, simple averaging is not far from what is done in practice. For example, when constructing probabilistic maps to label visual areas of the brain, Wang et al. (2015) validated their definition of borders between visual areas using the simple average of phase (i.e., polar angle, ϕ, in the pRF model). However, the simple average does not make use of all available information when the variance of each term in the average is known. Let αₖ denote a parameter estimate for subject k, with known variance, σ²(αₖ). (In this case, α is a placeholder for any other parameter, ρ, ϕ, σ, or n.) Using this notation, the simple average can be expressed as

$$\overline{α} = \frac{{\sum }_{k ∈ K} {α}_{k}}{\vert K \vert} \qquad ( 3 )$$

where K is the set of subjects included in the average, and |K| refers to the size of this set. In this case, the variance of α̅ equals

$$Var ( \overline{α} ) = \frac{{\sum }_{k ∈ K}^{} {σ}^{2} ( {α}_{k} )}{{\vert K \vert}^{2}} \qquad ( 4 )$$

However, the terms in the average can be weighted, and it is well-known that the inverse-variance weighted average, defined as

$$\hat{α} = \frac{{\sum }_{k ∈ K} {α}_{k} / {σ}^{2} ( {α}_{k} )}{{\sum }_{k ∈ K} 1 / {σ}^{2} ( {α}_{k} )} \qquad ( 5 )$$

is the weighted average that minimizes variance:

$$Var ( \hat{α} ) = \frac{1}{{\sum }_{k ∈ K} 1 / {σ}^{2} ( {α}_{k} )} \qquad ( 6 )$$

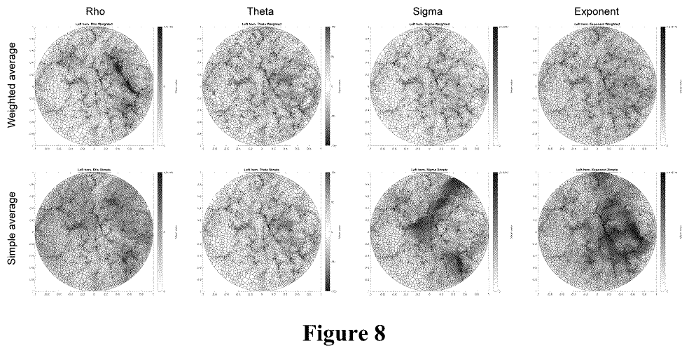

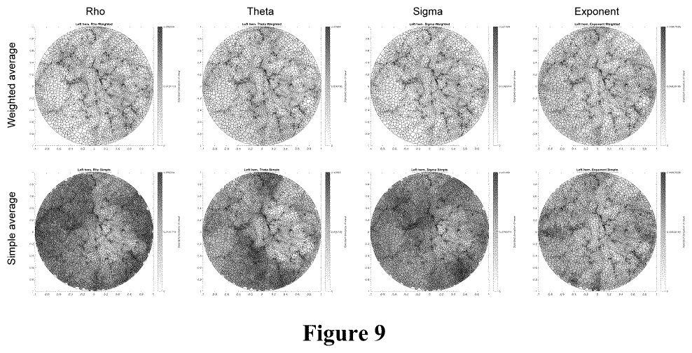

In FIG. 8, the exemplary results of the weighted average are compared to the results of the simple average (where visualizations of the average pRF are estimated for each parameter (column) using weighted averaging (top row) versus simple averaging (bottom row)), and in FIG. 9, the associated exemplary standard deviations on these averages are visualized. The It is evident in FIG. 9 that inverse-variance weighting can produce a more precise average with standard deviations about 4 times smaller in many cases. FIG. 8 shows that the effect of the two weighting schemes on the average values can be seen. For example, in the averages of ρ, inverse-variance weighting extended the dynamic range of the average eccentricity map, and also attenuated the eccentricity outside the region of the V1-V3 complex, mitigating influential outliers in these regions. Similar de-noising effects are observable in the average σ and n maps where large values in the simple average appear to be attenuated in the weighted average.

### Exemplary Discussion

With the exemplary embodiments of the present disclosure, the exemplary systems, methods, and computer accessible medium can be provided to facilitate a PRF model estimation, which is called qPRF. While the technique can utilize some initial pre-processing (e.g., approximately 4 hours for the parameter space defined herein) and also use some static memory consumption (e.g., approximately 8 GB), the time efficiency gained dramatically outweighs the relatively small upfront resource demands. In an exemplary analysis, the qPRF of the exemplary systems, methods, and computer accessible medium according to the exemplary embodiments of the present disclosure was able to provide estimates within

$${\frac{1}{1500}}^{th}$$

the time required for another popular package (analyzePRF) to accomplish the same task.

The qPRF of the exemplary systems, methods, and computer accessible medium according to the exemplary embodiments of the present disclosure can achieve a very high level of acceleration by making use of a specialized data structure which stores parameter combinations of the PRF model in a searchable tree structure. In the current implementation of the qPRF exemplary systems, methods, and computer accessible medium according to the exemplary embodiments of the present disclosure, the design and sampling density of the data structure can be based on an understanding of the range of parameters and measurement noise in retinotopic mapping experiments. However, it could be that these parameter ranges may still not be optimal for every application and might be subject to further optimized within the framework of the exemplary systems, methods, and computer accessible medium according to the exemplary embodiments of the present disclosure.

For example, the data structure may be further improved with machine learning approaches that can optimize the categorization of PRF predictions based on their functional similarities. This might yield a tree structure similar to that of the exemplary systems, methods, and computer accessible medium according to the exemplary embodiments of the present disclosure, except that the number of levels, the number of prototypes at each level, the number of combinations contained in the child parameter set of any single node, and the range of values represented by those parameter sets may differ. As another example, fixing n would further speed up the procedure by reducing the number of parameter combinations to be modeled in anticipation and subsequently searched during the search step. Further, some users may want to increase the sampling density to achieve better solutions.

The search procedure itself can also be changed based on user defined needs. In the implementation of the qPRF of the exemplary systems, methods, and computer accessible medium according to the exemplary embodiments of the present disclosure, a unidirectional search path is described, considering only the single optimal candidate at each level of the data structure. However, the data structure provided by qPRF can facilitate other search methods. For example, the search could consider the top 5 or 10 candidates at each level and all of their children. Although this increases the number of comparisons to be performed, the number of candidates to be considered in parallel can be tuned to the researcher's competing needs for precision and time efficiency. This alternative approach can be helpful in cases where, conditioned on a new estimate of n and/or σ, the optimal estimates of μₓ and μ_{y} change. Other search methods that the qPRF data structure of the exemplary systems, methods, and computer accessible medium according to the exemplary embodiments of the present disclosure can support include stochastic methods, where the children of a small number of nonoptimal candidates are searched as a security against optimizing to a local minimum.

The benefit of enhancing the usability of the exemplary PRF model can be two-fold. Firstly, in clinical settings, decisions must be made rapidly to offer patients the highest probability of a treatment's success. However, current implementations of the PRF model operate too slowly for the PRF model to be used for real-time decision making. Secondly, more empirical work remains to be done to unlock the applications alluded to above. For example, with respect to macular degeneration (MD), there remains some ambiguity about the role of plasticity in producing the cortical effect of MD (see, e.g., Bridge, 2011; Wandell and Smirnakis, 2009). Improving the usability of the PRF model will offer a greater pool of visual neuroscientists access to the tools necessary to resolve such ambiguities.

A dramatic acceleration of PRF decoding according to the exemplary systems, methods, and computer accessible medium according to the exemplary embodiments of the present disclosure can provide several additional possibilities.

Since the exemplary systems, methods, and computer accessible medium according to the exemplary embodiments of the present disclosure have provided a rapid estimation of the standard PRF model, exemplary systems, methods, and computer accessible medium according to the exemplary embodiments of the present disclosure can build on this framework to estimate more elaborate forms of the PRF model at similar speeds. Indeed, the exemplary systems, methods, and computer accessible medium according to the exemplary embodiments of the present disclosure can facilitate the estimating the exponent parameter, n, of the PRF model whereas in past literature, this was assumed to be fixed for simplicity (see, e.g., Benson et al., 2018). An elaboration of the PRF model where the techniques of qPRF may be applied is one where the receptive field is non-circular. In this case, the receptive field of a particular voxel on the visual field may be elliptically elongated with some orientation.

Although exemplary implementations of such a model may vary, this generalization introduces at least two additional parameters which must be estimated. Exemplary systems, methods, and computer accessible medium according to the exemplary embodiments of the present disclosure can implement this elliptical qPRF based on the existing qPRF data structure described here, but with one additional layer of parameter combinations added at the finest level to capture the additional variations in the receptive field shape. Although standard packages for PRF decoding do not consider this possibility, there are well-known perceptual phenomena, such as visual crowding (see, e.g., Whitney and Levi, 2011), wherein the perceptibility of a visual feature depends on how the feature is oriented in the visual field periphery, suggesting that the receptive field is elongated orthogonal to this orientation. Enabled by exemplary systems, methods, and computer accessible medium according to the exemplary embodiments of the present disclosure, a PRF decoder which accounts for non-circular receptive fields could be used by vision scientists to attribute crowding phenomena to specific cortical locus.

While the exemplary systems, methods, and computer accessible medium according to the exemplary embodiments of the present disclosure provide qPRF as a technique for minimizing the sum of squared deviations between the PRF model and a BOLD signal, other objective functions (such as likelihood) can be used within this same framework, revealing another application of qPRF: Bayesian inference. Bayesian inference has several advantages over traditional paradigms, such as the ability to condition a model of interest on prior data, offering a natural way to aggregate information across many studies and improve the precision of future estimates. However, Bayesian inference often relies on time-expensive numerical optimization techniques to approximate the posterior distribution of each parameter.

In a common Markov chain Monte Carlo (MCMC) approximation scheme, this can require the model of interest to be evaluated tens of thousands of times for each parameter, increasing the computation time severalfold. Using previous implementations of the PRF model, such a technique would be completely intractable. With the qPRF of the exemplary systems, methods, and computer accessible medium according to the exemplary embodiments of the present disclosure, such a scheme for Bayesian inference can be used naively and still offer time costs that are comparable to previous implementations of the simple, frequentist PRF model. Further, the data structure underlying qPRF can facilitate less naive approaches to Bayesian inference. In the qPRF of the exemplary systems, methods, and computer accessible medium according to the exemplary embodiments of the present disclosure, the data structure represents (with some resolution) the space of prediction curves that the PRF model can generate for a given set of stimuli. In using MCMC, one would typically assume that these curves are unknown and would use random sampling to try to adequately cover this space, so with qPRF, exemplary systems, methods, and computer accessible medium according to the exemplary embodiments of the present disclosure can form approximations of the posterior distribution more rapidly by searching this prediction space purposefully, since it is already known.

As discussed herein, the exemplary systems, methods, and computer accessible medium according to the exemplary embodiments of the present disclosure can be used to rapidly form independent estimates of the PRF model at each vertex, but the rapid acceleration achieved by qPRF now opens the possibility of considering the time series at multiple vertices simultaneously. This can be important because it is well-known that retinotopic maps on the visual field have topological properties (see, e.g., Tootell et al., 1988), but the PRF model has no mathematical constraint which forces estimates at neighboring vertices to obey the patterns known from physiology. One possible constraint comes from the use of Beltrami coefficient maps (see, e.g., BCMs; Tu et al., 2021), which can be used to detect whether the mapping from visual cortex to visual field violates the topological condition. In previous work, Tu et al. (2021) used BCMs in combination with smoothing techniques to manipulate retinotopic maps derived directly from the PRF model and enforce the topological condition upon them. However, this technique did not simultaneously account for the goodness-of-fit at each vertex, largely because existing implementations of the model would not allow this method to be completed within a reasonable time frame. With qPRF, the exemplary systems, methods, and computer accessible medium according to the exemplary embodiments of the present disclosure can take the topology-preserving methods of Tu et al. and update them by assessing the goodness-of-fit of the model at each vertex after every smoothing step. This can facilitate the user to specify optimal trade-offs between topological preservation and goodness-of-fit to the underlying time series.

Further, it may offer a more principled way to perform the smoothing itself. For example, in their smoothing step, Tu et al. took Beltrami coefficients exceeding 1 (indicating a topological violation) and changed them to a fixed value less than 1. With the qPRF of the exemplary systems, methods, and computer accessible medium according to the exemplary embodiments of the present disclosure, the adjusted value can be variable and optimally chosen to maximize goodness of fit to the underlying time series.

Further, the exemplary systems, methods, and computer accessible medium according to the exemplary embodiments of the present disclosure can provide an ability for fitting many other kinds of retinotopic mapping models. These can include the energy-based models of Benson et al. (2014) and template models used by Dougherty et al. (2003) and also Larsson and Heeger (2006), as well as Gaussian process models that are currently actively being developed (see, e.g., Waz et al., 2023; Waz et al., 2024). Similar to the work of Tu et al. (2021), these exemplary models generally do not consider the underlying time series while they are being fitted to the cortex of each subject; rather, an initial PRF estimate is formed and the model is fitted to these estimates as though they were noiseless observations. In this context, the qPRF of the exemplary systems, methods, and computer accessible medium according to the exemplary embodiments of the present disclosure will allow these models to be evaluated at the level of the time series rather than the PRF estimates, operating essentially as a link function between the retinotopic mapping model and the BOLD signal. This shift in modeling may lead to more informative models, e.g., through regularization or through estimation of measurement noise that is simultaneous to the model fitting procedure.

Additionally, the exemplary systems, methods, and computer accessible medium according to the exemplary embodiments of the present disclosure can provide immediate clinical applications for PRF through real-time analysis of fMRI. In behavioral science generally, it is often very important to consider what are the most informative testing conditions for a subject to experience. For this reason, adaptive methods (ranging from classical staircase methods as in Cornsweet, 1962, to more contemporary Bayesian adaptive methodologies as in Lesmes et al., 2010) are often used to tailor the experimental conditions on a trial-by-trial basis to lead to more precise estimates in shorter time. Although adaptive methods in the context of an fMRI procedure have been tried (see, e.g., Bahg et al., 2020), no such approaches have been tried in the context of retinotopic mapping. It is likely that the previously long wait time for PRF estimates posed an obstacle to this possibility. With exemplary systems, methods, and computer accessible medium according to the exemplary embodiments of the present disclosure, it may now be possible to generate PRF estimates while the subject remains in the scanner. Using real-time PRF estimates, stimuli and scanner parameters may be adapted to enhance the information gained with each scan. Further, it may even be possible to make use of these techniques in the context of neurosurgery, where a patient's brain function may be checked during operation to ensure that areas of visual function are not affected by ablation.

The qPRF of the exemplary systems, methods, and computer accessible medium according to the exemplary embodiments of the present disclosure can enable methods of uncertainty quantification to be performed within practical resource constraints, for example, as with the novel variational inference procedure of the exemplary systems, methods, and computer accessible medium according to the exemplary embodiments of the present disclosure discussed herein. The additional time consumption relative to the qPRF procedure alone can be small (e.g., about 4 times longer to compute), meaning that qPRF can be used to quantify variance in less time than other packages would require to achieve a point estimate. Related applications that qPRF of the exemplary systems, methods, and computer accessible medium according to the exemplary embodiments of the present disclosure can accelerate include Bayesian methods, hierarchical models, and machine learning paradigms that require the PRF model to be evaluated iteratively during a numerical fitting procedure. Uncertainty measures thereby gained can be used to identify where BOLD imagery provides the most information about retinotopic maps. Uncertainty measures thereby gained can also be used to enhance population-level retinotopic maps, for example, using inverse-variance weighted averaging as discussed herein to perform de-noising and to enhance precision and dynamic range

Given that the exemplary qPRF methods according to exemplary embodiments of the present disclosure allow variance quantification to be performed more quickly than previous methods, the exemplary systems, methods, and computer accessible medium according to the exemplary embodiments of the present disclosure can facilitate the discovery of applications where variability is a quantity of interest. For example, in studies of plasticity, it may be found that training reduces the variability in the pRF estimates, indicating that the pRF signal is represented more coherently in the BOLD response after some intervention. Similar phenomena might be observed in visual pathology, where disease progression might increase the variability of pRF estimates, or cross-species comparisons, where variance estimates might provide an adjustment for neurovascular differences.

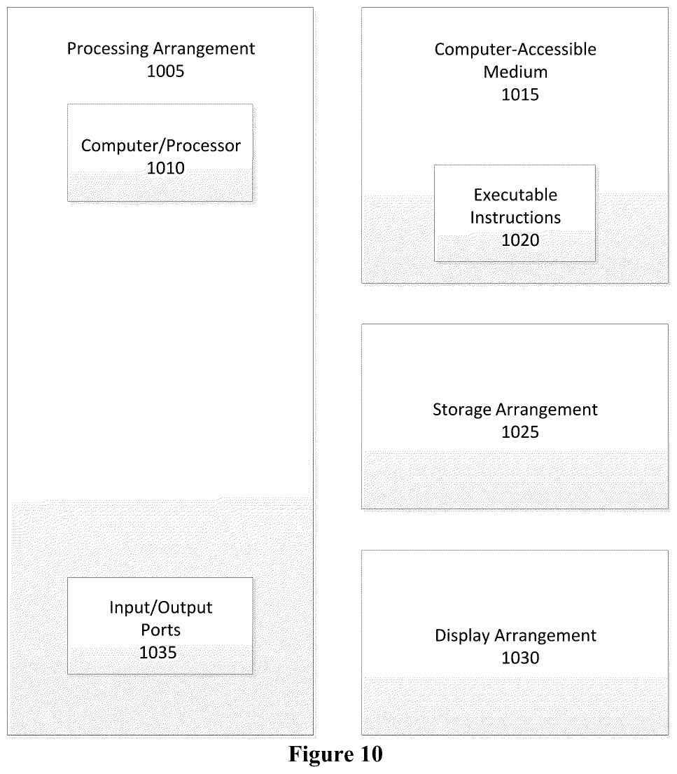

FIG. 10 shows a block diagram of an exemplary embodiment of a system according to the present disclosure. For example, exemplary procedures in accordance with the present disclosure described herein can be performed by a processing arrangement and/or a computing arrangement (e.g., computer hardware arrangement) 1005. Such processing/computing arrangement 1005 can be, for example entirely or a part of, or include, but not limited to, a computer/processor 1010 that can include, for example one or more microprocessors, and use instructions stored on a computer-accessible medium (e.g., RAM, ROM, hard drive, or other storage device).

As illustrated in FIG. 10, for example a computer-accessible medium 1015 (e.g., as described herein above, a storage device such as a hard disk, floppy disk, memory stick, CD-ROM, RAM, ROM, etc., or a collection thereof) can be provided (e.g., in communication with the processing arrangement 1005). The computer-accessible medium 1015 can contain executable instructions 1020 thereon. In addition or alternatively, a storage arrangement 1025 can be provided separately from the computer-accessible medium 1015, which can provide the instructions to the processing arrangement 1005 so as to configure the processing arrangement to execute certain exemplary procedures, processes, and methods, as described herein above, for example. Further, the exemplary processing arrangement 1005 can be provided with or include an input/output ports 1035, which can include, for example a wired network, a wireless network, the internet, an intranet, a data collection probe, a sensor, etc. As shown in FIG. 10, the exemplary processing arrangement 1005 can be in communication with an exemplary display arrangement 1030, which, according to certain exemplary embodiments of the present disclosure, can be a touch-screen configured for inputting information to the processing arrangement in addition to outputting information from the processing arrangement, for example. Further, the exemplary display arrangement 1030 and/or a storage arrangement 1025 can be used to display and/or store data in a user-accessible format and/or user-readable format.

According to the exemplary embodiments of the present disclosure, numerous specific details have been set forth. It is to be understood, however, that implementations of the disclosed technology can be practiced without these specific details. In other instances, well-known methods, structures and techniques have not been shown in detail in order not to obscure an understanding of this description. References to “some examples,” “other examples,” “one example,” “an example,” “various examples,” “one embodiment,” “an embodiment,” “some embodiments,” “example embodiment,” “various embodiments,” “one implementation,” “an implementation,” “example implementation,” “various implementations,” “some implementations,” etc., indicate that the implementation(s) of the disclosed technology so described may include a particular feature, structure, or characteristic, but not every implementation necessarily includes the particular feature, structure, or characteristic. Further, repeated use of the phrases “in one example,” “in one exemplary embodiment,” or “in one implementation” does not necessarily refer to the same example, exemplary embodiment, or implementation, although it may.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

While certain implementations of the disclosed technology have been described in connection with what is presently considered to be the most practical and various implementations, it is to be understood that the disclosed technology is not to be limited to the disclosed implementations, but on the contrary, is intended to cover various modifications and equivalent arrangements included within the scope of the appended claims. Although specific terms are employed herein, they are used in a generic and descriptive sense only and not for purposes of limitation.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification and drawings, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

Throughout the disclosure, the following terms take at least the meanings explicitly associated herein, unless the context clearly dictates otherwise. The term “or” is intended to mean an inclusive “or.” Further, the terms “a,” “an,” and “the” are intended to mean one or more unless specified otherwise or clear from the context to be directed to a singular form.

This written description uses examples to disclose certain implementations of the disclosed technology, including the best mode, and also to enable any person skilled in the art to practice certain implementations of the disclosed technology, including making and using any devices or systems and performing any incorporated methods.

### EXEMPLARY REFERENCES

1. G. Bahg, P. B. Sederberg, J. I. Myung, X. Li, M. A. Pitt, Z.-L. Lu, and B. M. Turner. Real-time Adaptive Design Optimization Within Functional MRI Experiments. Computational Brain & Behavior, 3(4):400-429, 2020. ISSN 2522087X. doi: 10.1007/s42113-020-00079-7. URL https://doi.org/10.1007/s42113-020-00079-7.
2. C. I. Baker, E. Peli, N. Knouf, and N. G. Kanwisher. Reorganization of visual processing in macular degeneration. Journal of Neuroscience, 25(3):614-618, 2005.
3. A. Barbot, A. Das, M. D. Melnick, M. R. Cavanaugh, E. P. Merriam, D. J. Heeger, and K. R. Huxlin. Spared perilesional VI activity underlies training induced recovery of luminance detection sensitivity in cortically-blind patients. Nature Communications, 12(1):6102 October 2021. ISSN 2041-1723. doi: 10.1038/s41467-021-26345-1. URL https://www.nature.com/articles/s41467-021-26345-1. Publisher: Nature Publishing Group.
4. N. C. Benson, O. H. Butt, D. H. Brainard, and G. K. Aguirre. Correction of Distortion in Flattened Representations of the Cortical Surface Allows Prediction of V1-V3 Functional Organization from Anatomy. PLOS Computational Biology, 10(3):e1003538, March 2014. ISSN 1553-7358. doi: 10.1371/journal. pcbi.1003538. URL https://journals.plos.org/ploscompbiol/article?id=10.1371/journal.pcbi.1003538. Publisher: Public Library of Science.
5. N. C. Benson, K. W. Jamison, M. J. Arcaro, A. T. Vu, M. F. Glasser, T. S. Coalson, D. C. Van Essen, E. Yacoub, K. Ugurbil, J. Winawer, and K. Kay. The Human Connectome Project 7 Tesla retinotopy dataset: Description and population receptive field analysis. Journal of Vision, 18(13):23, 2018. ISSN 1534-7362. doi: 10.1167/18.13.23. URL https://doi.org/10.1167/18.13.23.
6. N. C. Benson, J. M. D. Yoon, D. Forenzo, S. A. Engel, K. N. Kay, and J. Winawer. Variability of the Surface Area of the V1, V2, and V3 Maps in a Large Sample of Human Observers. Journal of Neuroscience, 42(46):8629-8646 November 2022. ISSN 0270-6474,1529-2401. doi: 10.1523/JNEUROSCI.0690-21.2022. URL https://www.jneurosci.org/content/42/46/8629. Publisher: Society for Neuroscience Section: Research Articles.
7. C. C. Boucard, A. T. Hernowo, R. P. Maguire, N. M. Jansonius, J. B. Roerdink, J. M. Hooymans, and F. W. Cornelissen. Changes in cortical grey matter density associated with long-standing retinal visual field defects. Brain, 132(7):1898-1906, 2009.
8. A. A. Brewer and B. Barton. Visual cortex in aging and Alzheimer's disease: changes in visual field maps and population receptive fields. Frontiers in Psychology, 5, February 2014. ISSN 1664-1078. doi: 10.3389/fpsyg.2014.
9. 00074. URL https://www.frontiersin.org/journals/psychology/articles/10.3389/fpsyg.2014.00074/full. Publisher: Frontiers.
10. A. A. Brewer, B. Barton, A. A. Brewer, and B. Barton. Changes in Visual Cortex in Healthy Aging and Dementia. In Update on Dementia. IntechOpen, September 2016. ISBN 978-953-51-2655-3. doi: 10.5772/64562. URL https://www.intechopen.com/chapters/52137.
11. H. Bridge. Mapping the visual brain: how and why. Eye, 25(3):291-296, March 2011. ISSN 0950-222X. doi: 10.1038/eye.2010.166. URL https://www.ncbi.nlm.nih.
12. gov/pmc/articles/PMC3178304/.
13. T. N. Cornsweet. The Staircase-Method in Psychophysics. 75(3):485-491, 1962. ISSN 0002-9556. doi: 10.2307/1419876. URL https://www.jstor.org/stable/1419876.
14. E. A. De Yoe, G. J. Carman, P. Bandettini, S. Glickman, J. Wieser, R. Cox, D. Miller, and J. Neitz. Mapping striate and extrastriate visual areas in human cerebral cortex. Proceedings of the National Academy of Sciences of the United States of America, 93(6):2382-2386 March 1996. ISSN 0027-8424. URL https://www.ncbi.
15. nlm.nih.gov/pmc/articles/PMC39805/.
16. R. F. Dougherty, V. M. Koch, A. A. Brewer, B. Fischer, J. Modersitzki, and B. A. Wandell. Visual field representations and locations of visual areas V1/2/3 in human visual cortex. Journal of Vision, 3(10):1, October 2003. ISSN 1534-7362. doi: 10.1167/3.10.1. URL https://doi.org/10.1167/3.10.1.
17. S. O. Dumoulin and B. A. Wandell. Population receptive field estimates in human visual cortex. NeuroImage, 39(2):647-660, 2008. ISSN 1053-8119. doi: 10.1016/j.neuroimage.2007.09.034. URL https://www.sciencedirect.com/science/article/pii/S1053811907008269.
18. S. O. Dumoulin, R. D. Hoge, C. L. Baker Jr, R. F. Hess, R. L. Achtman, and A. C. Evans. Automatic volumetric segmentation of human visual retinotopic cortex. Neuroimage, 18(3):576-587, 2003.
19. R. O. Duncan, P. A. Sample, R. N. Weinreb, C. Bowd, and L. M. Zangwill. Retinotopic organization of primary visual cortex in glaucoma: a method for comparing cortical function with damage to the optic disk. Investigative ophthalmology & visual science, 48(2):733-744, 2007.
20. J. Elshout, D. Bergsma, A. van den Berg, and K. Haak. Functional MRI of visual cortex predicts training-induced recovery in stroke patients with homonymous visual field defects. NeuroImage: Clinical, 31:102703, January 2021. ISSN 2213-1582. doi: 10.1016/j.nicl.2021.102703. URL https://www.sciencedirect.
21. com/science/article/pii/S2213158221001479. Publisher: Elsevier.
22. S. A. Engel, D. E. Rumelhart, B. A. Wandell, A. T. Lee, G. H. Glover, E.-J. Chichilnisky, M. N. Shadlen, et al. fmri of human visual cortex. Nature, 369(6481):525-525, 1994.
23. S. A. Engel, G. H. Glover, and B. A. Wandell. Retinotopic organization in human visual cortex and the spatial precision of functional MRI. Cerebral Cortex (New York, N.Y.: 1991), 7(2):181-192, March 1997. ISSN 1047-3211. doi: 10.1093/cercor/7.2.181.
24. P. T. Fox, M. A. Mintun, M. E. Raichle, F. M. Miezin, J. M. Allman, and D. C. Van Essen. Mapping human visual cortex with positron emission tomography. Nature, 323(6091):806-809, 1986.
25. P. T. Fox, F. M. Miezin, J. M. Allman, D. C. Van Essen, and M. E. Raichle. Retinotopic organization of human visual cortex mapped with positron-emission tomography. Journal of Neuroscience, 7(3):913-922, 1987.
26. M. Glickstein and D. Whitteridge. Tatsuji inouye and the mapping of the visual fields on the human cerebral cortex. Trends in Neurosciences, 10(9):350-353, 1987.
27. K. V. Haak, J. Winawer, B. M. Harvey, R. Renken, S. O. Dumoulin, B. A. Wandell, and F. W. Cornelissen. Connective field modeling. NeuroImage, 66:376-384, 2013. ISSN 1053-8119. doi: 10.1016/j.neuroimage.2012.10.037. URL https://www.sciencedirect.com/science/article/pii/S1053811912010403.
28. K. Hense, T. Plank, C. Wendl, F. Dodoo-Schittko, E. Bumes, M. W. Greenlee, N. O. Schmidt, M. Proescholdt, and K. Rosengarth. fMRI Retinotopic Mapping in Patients with Brain Tumors and Space-Occupying Brain Lesions in the Area of the Occipital Lobe. Cancers, 13(10):2439 May 2021. ISSN 2072-6694. doi: 10.3390/cancers13102439.
29. M. M. Himmelberg, E. Tu\ddot{ }n,cok, J. Gomez, K. Grill-Spector, M. Carrasco, and J. Winawer. Comparing retinotopic maps of children and adults reveals a latestage change in how v1 samples the visual field. Nature Communications, 14(1):1561 March 2023. ISSN 2041-1723. doi: 10.1038/s41467-023-37280-8. URL https://www.nature.com/articles/s41467-023-37280-8. Publisher: Nature Publishing Group.
30. G. Holmes and W. Lister. Disturbances of vision from cerebral lesions, with special reference to the cortical representation of the macula. Brain, 39(1-2):34-73, 1916.
31. T. Inouye. Die Sehst\ddot{ }orungen bei Schussverletzungen der kortikalen Sehsph\ddot{ }are: nach Beobachtungen an Verwundeten der letzten japanischen Kriege. Engelmann, 1909.
32. K. N. Kay, J. Winawer, A. Mezer, and B. A. Wandell. Compressive spatial summation in human visual cortex. Journal of Neurophysiology, 110(2):481-494, 2013. ISSN 0022-3077. doi: 10.1152/jn.00105.2013. URL https://journals.physiology. org/doi/full/10.1152/jn.00105.2013.
33. J. Larsson and D. J. Heeger. Two Retinotopic Visual Areas in Human Lateral Occipital Cortex. Journal of Neuroscience, 26(51):13128-13142, December 2006. ISSN 0270-6474 1529-2401. doi: 10.1523/JNEUROSCI.1657-06.2006. URL https://www.jneurosci.org/content/26/51/13128. Publisher: Society for Neuroscience Section: Articles.
34. P. Lauro, S. Lee, M. Ahn, A. Barborica, and W. Asaad. DBStar: An OpenSource Tool Kit for Imaging Analysis with Patient-Customized Deep Brain Stimulation Platforms. Stereotactic and Functional Neurosurgery, 96(1):13-21, February 2018. ISSN 1011-6125. doi: 10.1159/000486645. URL https://doi.org/10. 1159/000486645.
35. L. A. Lesmes, Z.-L. Lu, J. Baek, and T. D. Albright. Bayesian adaptive estimation of the contrast sensitivity function: The quick CSF method. Journal of Vision, 10(3):17, 2010. ISSN 1534-7362. doi: 10.1167/10.3.17. URL https://doi.org/10. 1167/10.3.17.
36. F. Ribeiro, N. Benson, and A. Puckett. Human Retinotopic Mapping: from Empirical to Computational Models of Retinotopy. March 2024. doi: 10.31234/osf.io/7eu9m.
37. M. I. Sereno, A. M. Dale, J. B. Reppas, K. K. Kwong, J. W. Belliveau, T. J. Brady, B. R. Rosen, and R. B. H. Tootell. Borders of Multiple Visual Areas in Humans Revealed by Functional Magnetic Resonance Imaging. Science, 268(5212):889-893, May 1995. doi: 10.1126/science.7754376. URL https://www.science. org/doi/10.1126/science.7754376. Publisher: American Association for the Advancement of Science.
38. M. A. Silver and S. Kastner. Topographic maps in human frontal and parietal cortex. Trends in Cognitive Sciences, 13(11):488-495, November 2009. ISSN 13646613. doi: 10.1016/j.tics.2009.08.005. URL https://www.sciencedirect.com/science/article/pii/S1364661309001739.
39. A. Smith, K. Singh, A. Williams, and M. Greenlee. Estimating Receptive Field Size from fMRI Data in Human Striate and Extrastriate Visual Cortex. Cerebral Cortex, 11(12):1182-1190 December 2001. ISSN 1047-3211. doi: 10.1093/cercor/11.12.
40. 1182. URL https://doi.org/10.1093/cercor/11.12.1182.
41. D. Ta, Y. Tu, Z.-L. Lu, and Y. Wang. Quantitative characterization of the human retinotopic map based on quasiconformal mapping. Medical Image Analysis, 75:102230, January 2022. ISSN 1361-8415. doi: 10.1016/j.media.2021.102230. URL https://www.sciencedirect.com/science/article/pii/S1361841521002759.
42. R. B. Tootell, E. Switkes, M. S. Silverman, and S. L. Hamilton. Functional anatomy of macaque striate cortex. ii. retinotopic organization. Journal of neuroscience, 8(5):1531-1568, 1988.
43. Y. Tu, D. Ta, Z.-L. Lu, and Y. Wang. Topology-preserving smoothing of retinotopic maps. PLOS Computational Biology, 17(8):e1009216, 2021. ISSN 15537358. doi: 10.1371/journal.pcbi.1009216. URL https://journals.plos.org/ploscompbiol/article?id=10.1371/journal.pcbi.1009216.
44. B. A. Wandell and S. M. Smirnakis. Plasticity and stability of visual field maps in adult primary visual cortex. Nature reviews. Neuroscience, 10(12):873-884, December 2009. ISSN 1471-003X. doi: 10.1038/nrn2741. URL https://www.ncbi.nlm. nih.gov/pmc/articles/PMC2895763/.
45. L. Wang, R. E. B. Mruczek, M. J. Arcaro, S. Kastner. Probabilistic Maps of Visual Topography in Human Cortex. Cerebral Cortex, 25:3911-3931. October 2015. doi: 10.1093/cercor/bhu277.
46. S. Waz, Y. Wang, and Z.-L. Lu. Improving human retinotopic mapping with a gaussian process model. In Meeting of the Society for Neuroscience, November 2023.
47. S. Waz, Y. Wang, and Z.-L. Lu. Hierarchical gaussian process model for human retinotopic mapping. In 24th Annual Meeting of the Vision Sciences Society, May 2024.
48. D. Whitney and D. M. Levi. Visual Crowding: A fundamental limit on conscious perception and object recognition. 15(4):160-168, 2011. ISSN 1364-6613. doi: 10. 1016/j.tics.2011.02.005. URL https://www.ncbi.nlm.nih.gov/pmc/articles/PMC3070834/.
49. P. Zeidman, E. H. Silson, D. S. Schwarzkopf, C. I. Baker, and W. Penny. Bayesian population receptive field modelling. Neuroimage, 180(Pt A):173-187, October 2018. ISSN 1053-8119. doi: 10.1016/j.neuroimage.2017.09.008. URL https://www.ncbi.nlm.nih.gov/pmc/articles/PMC7417811/.

What is claimed is:

1. A method for decoding a population receptive field (PRF) model, comprising:
a) generating or providing a plurality of prototypes within a visual field, wherein each of the prototypes comprises an output prediction for the PRF model based on a predetermined stimulus and at least one unique parameter combination;
b) automatically identifying, from the plurality of prototypes, a closest matching prototype for a blood-oxygenation-level-dependent (BOLD) signal;
c) electronically searching a group of parameter combinations associated with the closest matching prototype to determine a refined parameter combination that more closely matches the BOLD signal than the closest matching prototype;
d) reiterating procedure (c) among at least one neighbor of the refined parameter combination until no neighboring combination improves the match; and
e) automatically estimating an uncertainty measure associated with the refined parameter combination using a variational inference procedure or another Bayesian inference method.

2. The method of claim 1, further comprising:
determining a further unique parameter combination by comparing the unique parameter combination determined from a first group of the parameter combinations which are unique with a second group of the parameter combinations which are unique related to the first group by searching a further group of the combinations that are unique that are related to the determined unique ones of the parameter combination.

3. The method of claim 1, wherein a specific group of related unique ones of the parameter combinations vary one or more parameters related to a receptive field location.

4. The method of claim 2, wherein a further group of unique ones of the parameter combinations vary one or more parameters related to at least one of a receptive field size and a compressive non-linearity for an identified receptive field location.

5. The method of claim 1, wherein the decoding is applied to a non-circular receptive field shape.

6. The method of claim 5, wherein the non-circular receptive shape is obtained by elongating a circular receptive field on a visual field along with a given orientation.

7. The method of claim 1, wherein the uncertainty measure comprises a posterior variance or an entropy associated with a receptive field estimate.

8. The method of claim 1, further comprising:
aggregating a group of parameter estimates across a plurality of voxels using inverse-variance weighting to produce a population-level retinotopic map.

9. The method of claim 1, further comprising:
identifying at least one spatial region of a cortical surface or a visual field where BOLD data provides a level of high information content based on the uncertainty measure being below a defined threshold.

10. The method of claim 1, wherein the variational inference procedure comprises approximating a posterior distribution using a multivariate Gaussian or log-normal distribution parameterized by mean and variance terms that are optimized with respect to an evidence-lower-bound (ELBO).

11. A system for decoding a population receptive field (PRF) model, comprising:
at least one processor configured to:
a) generate or provide a plurality of prototypes within a visual field, wherein each of the prototypes comprises an output prediction for the PRF model based on a predetermined stimulus and at least one unique parameter combination;
b) identify, from the plurality of prototypes, a closest matching prototype for a blood-oxygenation-level-dependent (BOLD) signal;
c) search a group of parameter combinations associated with the closest matching prototype to determine a refined parameter combination that more closely matches the BOLD signal than the closest matching prototype;
d) reiterate procedure (c) among at least one neighbor of the refined parameter combination until no neighboring combination improves the match; and
e) estimate an uncertainty measure associated with the refined parameter combination using a variational inference procedure or another Bayesian inference method.

12. The system of claim 11, wherein the at least one processor is further configured to determine a further unique parameter combination by comparing the unique parameter combination determined from a first group of the parameter combinations which are unique and related with a second group of the parameter combinations which are unique related to the first group by searching a further group of the parameter combinations related to the determined unique ones of the parameter combination.

13. The system of claim 11, wherein the specific group of related unique ones of the parameter combinations vary one or more parameters related to a receptive field location.

14. The system of claim 12, wherein a further group of unique ones of the parameter combinations vary one or more parameters related to at least one of a field size and a compressive non-linearity for an identified field location.

15. The system of claim 11, wherein the decoding is applied to a non-circular receptive field shape.

16. The system of claim 15, wherein the non-circular shape is obtained by elongating a circular receptive field on the visual field along with a given orientation.

17. The system of claim 11, wherein the uncertainty measure comprises a posterior variance or an entropy associated with a receptive field estimate.

18. The system of claim 11, wherein the at least one processor is further configured to aggregate a group of parameter estimates across a plurality of voxels using inverse-variance weighting to produce a population-level retinotopic map.

19. The system of claim 11, wherein the at least one processor is further configured to identify at least one spatial region of a cortical surface or a visual field where BOLD data provides a level of high information content based on the uncertainty measure being below a defined threshold.

20. The system of claim 11, wherein the variational inference procedure comprises approximating a posterior distribution using a multivariate Gaussian or log-normal distribution parameterized by mean and variance terms that are optimized with respect to an evidence-lower-bound (ELBO).

21. A non-transitory computer accessible medium which includes software thereon for decoding a population receptive field (PRF) model wherein, when at least one computer processor executes the software, the computer processor is configured to perform the procedures, comprising:
a) generating or providing a plurality of prototypes within a visual field, wherein each of the prototypes comprises an output value for the PRF model based on a predetermined stimulus and at least one unique parameter combination;
b) identifying, from the plurality of prototypes, a closest matching prototype for a blood-oxygenation-level-dependent (BOLD) signal;
c) searching a group of parameter combinations associated with the closest matching prototype to determine a refined parameter combination that more closely matches the BOLD signal than the closest matching prototype;
d) reiterating procedure (c) among at least one neighbor of the refined parameter combination until no neighboring combination improves the match; and
e) estimating an uncertainty measure associated with the refined parameter combination using a variational inference procedure or another Bayesian inference method.

22. The non-transitory computer accessible medium of claim 21, wherein the computer processor is further configured to determine a further unique parameter combination by comparing the unique parameter combination determined from a first group of the parameter combinations which are related and unique with a second group of the parameter combinations which are unique related to the first group by searching a further group the unique parameter combinations related to the determined unique ones of the parameter combination.

23. The non-transitory computer accessible medium of claim 21, wherein the specific group of related unique ones of the parameter combinations vary one or more parameters related to a receptive field location.

24. The non-transitory computer accessible medium of claim 22, wherein the further group of unique ones of the parameter combinations vary one or more parameters related to at least one of a field size and a compressive non-linearity for an identified field location.

25. The non-transitory computer accessible medium of claim 21, wherein the decoding is applied to a non-circular receptive field shape.

26. The non-transitory computer accessible medium of claim 25, wherein the non-circular shape is obtained by elongating a circular receptive field on the visual field along with a given orientation.

27. The non-transitory computer accessible medium of claim 21, wherein the uncertainty measure comprises a posterior variance or an entropy associated with a receptive field estimate.

28. The non-transitory computer accessible medium of claim 21, wherein the computer processor is further configured to aggregate a group of parameter estimates across a plurality of voxels using inverse-variance weighting to produce a population-level retinotopic map.

29. The non-transitory computer accessible medium of claim 21, wherein the computer processor is further configured to identify at least one spatial region of a cortical surface or a visual field where BOLD data provides a level of high information content based on the uncertainty measure being below a defined threshold.

30. The non-transitory computer accessible medium of claim 21, wherein the variational inference procedure comprises approximating a posterior distribution using a multivariate Gaussian or log-normal distribution parameterized by mean and variance terms that are optimized with respect to an evidence-lower-bound (ELBO).

31. A method for decoding a population receptive field (PRF) model, comprising:
generating a set of PRF estimates while a subject is in a functional magnetic resonance imaging scanner by determining a plurality of intervoxel relationships in real-time.
